(19) United States
(12) Patent Application Publication
(10) Pub. No.: US 2012/0273027 A1
(43) Pub. Date: Nov. 1, 2012

(54) INSULATING ROOFING/SIDING

(76) Inventor: JULIA KRYSTAL CONVERY, Round Rock, TX (US)

(21) Appl. No.: 13/097,374

(22) Filed: Apr. 29, 2011

(51) Int. Cl. H01L 31/048; H01L 31/02; H01L 31/0203; B32B 3/00

(52) U.S. Cl. 136/251; 428/57; 136/252; 136/259

(57) ABSTRACT

A roofing/siding material may be formed of a foam material, typically a poly foam, that may formed to look like roofing or siding, but may have increased insulation and sound-proofing properties, and may be lighter in weight, as compared to conventional materials. The roofing/siding material may be formed in sheets or planks that may interlock to cover a larger surface area. The roofing/siding material may include solar photovoltaic cells formed directly on the roofing/siding material. The roofing/siding material may save on energy costs, may be light weight (resulting in ease of installation and lower shipping costs), may be long lasting, and may be shaped and/or colored into cosmetically pleasing shapes and designs. The roofing/siding material may be formed to look like, for example, tile, wood, slate, roofing and siding exterior materials.

### BACKGROUND OF THE INVENTION

The present invention relates to roofing and siding materials and, more particularly, to a roofing/siding that is an exterior insulation, made to look like roofing and siding, made in planks and sheets.

Conventional roofing or siding materials often provide minimal insulation R-values while also providing little sound insulation. Moreover, conventional roofing or siding materials are often heavy and lack the ability to be easily shaped.

Conventional solar panels are often disposed on a home's or business' roof to collect solar energy. These solar panels are often not attractive, so much so that some homeowner associations forbid the use of roof-mount solar panels in their neighborhoods.

As can be seen, there is a need for roofing or siding that can be formed in various attractive shapes and sizes. while providing insulation and sound-proofing, and while optionally providing the ability to incorporate solar panels directly into the roofing or siding material.

### SUMMARY OF THE INVENTION

In one aspect of the present invention, a building material comprises a poly foam material having an exterior side, shaped to match conventional roofing or siding material, and a base forming a flat interior side; one or more holes through the base for attaching the poly foam material to a surface; and an overlap, wherein one or more features of the exterior side of one poly foam material overlap onto an adjacent poly foam material, covering the one or more holes of the adjacent poly foam material.

These and other features, aspects and advantages of the present invention will become better understood with reference to the following drawings, description and claims.

### BRIEF DESCRIPTION OF THE DRAWINGS

FIG. 1 is a perspective view of a roofing/siding material according to an exemplary embodiment of the present invention;

FIG. 2 is a perspective view of a roofing/siding module according to another exemplary embodiment of the present invention;

FIG. 3 is a plan view of the roofing/siding module of FIG. 2, showing overlap of multiple modules;

FIG. 4 is a perspective view of a ridge element according to an exemplary embodiment of the present invention; and

FIG. 5 is a perspective view of the roofing/siding module of FIG. 2 including a flexible solar array formed therein.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, an embodiment of the present invention provides a roofing/siding material that may be formed of a foam material, typically a poly foam, that may formed to look like roofing or siding, but may have increased insulation and sound-proofing properties, and may be lighter in weight, as compared to conventional materials. The roofing/siding material may be formed in sheets or planks that may interlock to cover a larger surface area. The roofing/siding material may include solar photovoltaic cells formed directly on the roofing/siding material. The roofing/siding material may save on energy costs, may be light weight (resulting in ease of installation and lower shipping costs), may be long lasting, and may be shaped and/or colored into cosmetically pleasing shapes and designs. The roofing/siding material may be formed to look like, for example, tile, wood, slate, roofing and siding exterior materials.

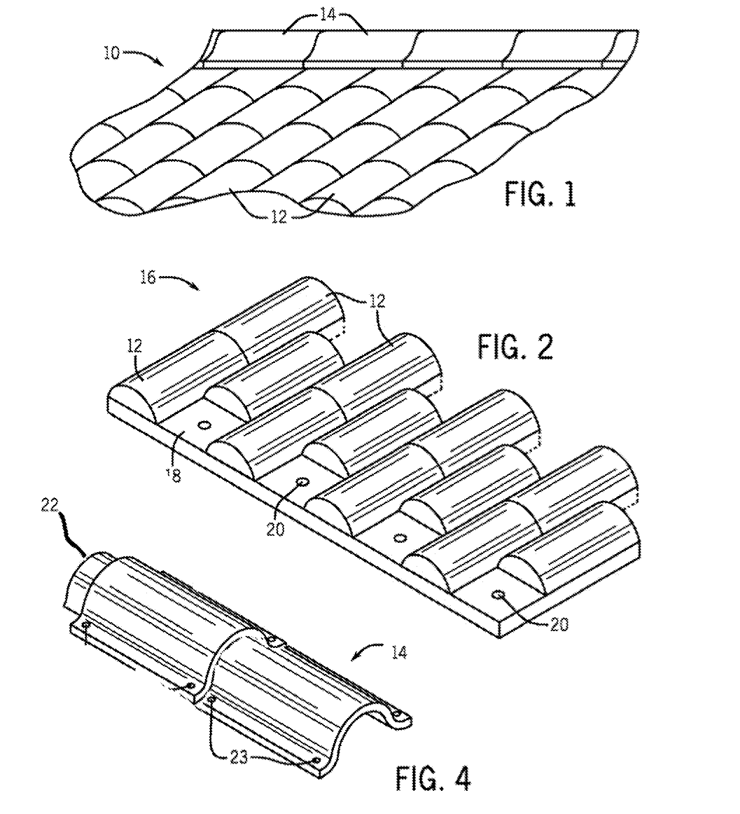

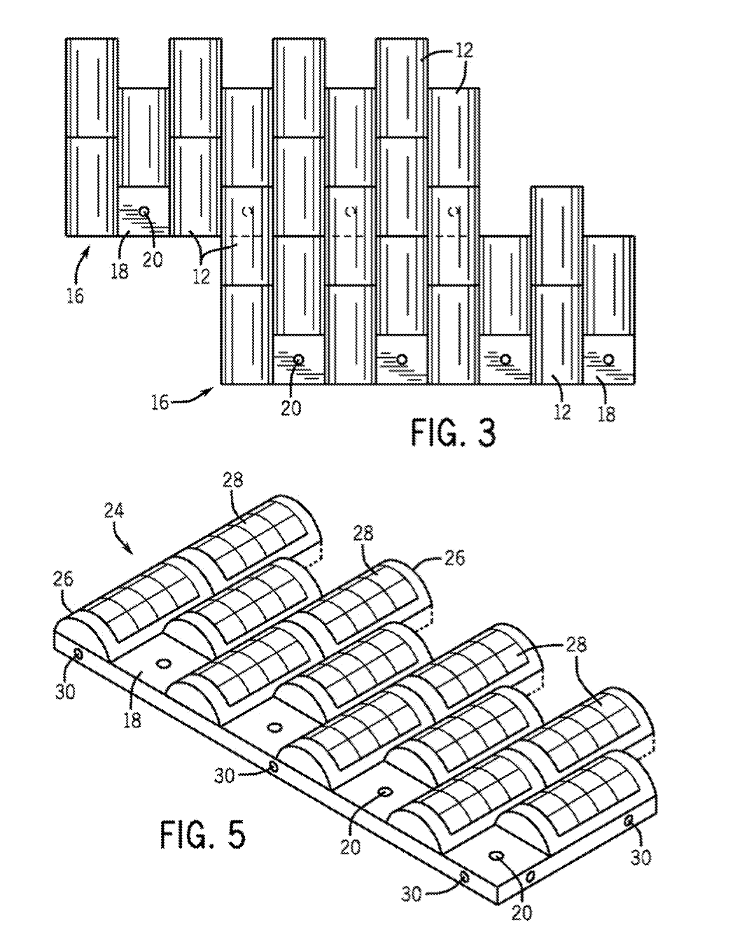

Referring to FIGS. 1 through 3, a roofing material 10 may be made of separate roofing modules 16 that may overlap in various manners. For example, the roofing modules 16 may be designed with an exterior surface that may appear like a tile roof, where a tile 12 from one module 16 may overlap over a base section 18 of another module. The base section 18 may be flat on an interior side (opposite the above described designed exterior surface) and may include holes 20 to attach the module 16 onto a roof undersheeting (not shown). In some embodiments of the present invention, the base section 18 may extend outward over one side of the module 16 and the tile 12 may extend over another side of the module 16, providing side-to-side overlap in addition to top to bottom overlap. While FIGS. 1 through 3 show a half-round, tile-like roof design, other designs of the roofing material 10 may be included within the scope of the present invention. The modules 16 may be made in any convenient size, typically from about 2 to about 6 feet wide and from about 2 to about 16 feet long. Often, the modules 16 may be formed in conventional sheet sizes, such as 4 foot by 8 foot sheets.

Referring to FIG. 4, a roof ridge unit 14 may be designed to cover a roof ridge. The roof ridge unit 14 may include an interlocking protrusion 22 at one end thereof, to fit under an opposite end of an adjacent roof ridge unit 14. A plurality of mounting holes 23 may be formed in the roof ridge unit 14 to attach the roof ridge units 14 to a roof. The roof ridge unit 14 may be formed in various lengths, typically from about 6 inches to about 16 feet in length, depending on the desired look of the end result. In some embodiments, the roof ridge unit 14 may have a design formed along its length. For example, FIG. 1 shows four full roof ridge units 14, however, a single unit may be designed to give the appearance of four separate roof ridge units 14.

Referring to FIG. 5, a solar module 24 may include tile-appearing members 26 (hereinafter, tile 26) having photovoltaics cells 28 attached thereto. In some embodiments, as shown in FIG. 5, each tile 26 may include a solar panel 28 on at least a portion thereof. In other embodiments, only a portion of the tiles 26 of the module 24 may include the photovoltaics cells 28. The solar modules 24 may include connections 30 for wiring the modules 24 together. The solar modules 24 may provide power to the structure on which there are used. In some embodiments, the tiles 26 of the solar module 24 may have grooves cut therein to receive the solar panels 28, thereby providing a flush mount of the solar panels 28 into the tiles 26.

The modules 16, 24 of the present invention may be formed of a poly foam. The poly foam may have color added to it during the manufacturing process. The poly foam may be, for example, blown into a mold that is shaped like a sheet or plank in the exterior design desired by the user. The mold may have wiring already disposed therein to provide electrical connections for the solar panels installed in the roofing/siding. The modules 16, 24 may have an ultraviolet (UV) elastomeric coating sprayed on the top surface thereof to protect the modules 16, 24 from harmful solar rays.

It should be understood, of course, that the foregoing relates to exemplary embodiments of the invention and that modifications may be made without departing from the spirit and scope of the invention as set forth in the following claims.

What is claimed is:

1. A building material comprising:
a poly foam material having an exterior side, shaped to match conventional roofing or siding material, and a base forming a flat interior side;
one or more holes through the base for attaching the poly foam material to a surface; and
an overlap, wherein one or more features of the exterior side of one poly foam material overlap onto an adjacent poly foam material, covering the one or more holes of the adjacent poly foam material.

2. The building material of claim 1, further comprising an ultraviolet elastomeric coating disposed on the exterior side.

3. The building material of claim 1, further comprising at least one solar photovoltaic sheet disposed on the exterior surface.

4. The building material of claim 3, wherein the at least one solar panel is disposed in a groove in the exterior surface, wherein the solar panel is flush with the surrounding exterior side of the poly foam material.

5. The building material of claim 3, further comprising wiring formed integrally in the poly foam material, the wiring electrically connected to each of the at least one solar panel.

6. The building material of claim 5, further comprising connections along an edge of the poly foam material, the connections adapted to electrically connect one poly foam material to an adjacent poly form material.

7. The building material of claim 6, wherein a plurality of solar photovoltaics cells are disposed in the poly foam material.

8. The building material of claim 1, wherein the building material is roofing.

9. The building material of claim 7, further comprising at least one ridge element, the ridge element having an interlocking protrusion to connect adjacent ones of the ridge element.

10. The building material of claim 1, wherein the poly foam material is formed as a sheet.
